(19) United States
(12) Patent Application Publication
(10) Pub. No.: US 2014/0159003 A1
(43) Pub. Date: Jun. 12, 2014

(54) ORGANIC LIGHT EMITTING DIODE DISPLAY DEVICE AND METHOD OF FABRICATING THE SAME

(71) Applicant: LG DISPLAY CO., LTD., Seoul (KR)

(72) Inventor: Young-Hoon Shin, Gyeonggi-do (KR)

(73) Assignee: LG DISPLAY CO., LTD., Seoul (KR)

(21) Appl. No.: 14/083,681

(22) Filed: Nov. 19, 2013

(30) Foreign Application Priority Data
Dec. 7, 2012 (KR) 10-2012-0141702

(51) Int. Cl. H01L 51/52; H01L 27/32

(52) U.S. Cl. CPC H01L 51/5253; H01L 27/3244
USPC 257/40; 438/26

(57) ABSTRACT

An organic light emitting diode (OLED) display device wherein permeation of moisture and oxygen thereinto is prevented and a method of manufacturing the OLED display device are disclosed. The OLED display device includes a substrate, an OLED including a first electrode, an organic emission layer, and a second electrode sequentially formed on the substrate, a protective film formed on the OLED, an encapsulation substrate adhered to an entire surface of the protective film via an adhesive, and a side protective film consisting of a silica film formed by curing a polysilazane solution so as to surround an exterior of elements between the substrate and the encapsulation substrate.

This application claims the benefit of Korean Patent Application No. 10-2012-0141702, filed on Dec. 7, 2012, which is hereby incorporated by reference as if fully set forth herein.

### BACKGROUND OF THE INVENTION

1. Field of the Invention

The present invention relates to an organic light emitting diode display device wherein permeation of moisture and oxygen thereinto may be prevented and a method of manufacturing the same.

2. Discussion of the Related Art

Image display devices, which display a variety of information on a screen, are a core technology of information and communication and are becoming increasingly thinner, lighter, more portable, and higher performance. Thus, organic light emitting diode (OLED) display devices, which display an image by controlling light emission of an organic emission layer (EML), have received attention as a flat panel display device that may address problems in terms of weight and volume associated with cathode ray tubes (CRTs).

Such OLED display devices include OLEDs, which are self-emissive devices using a thin EML between electrodes, and can be fabricated as a thin film with a thickness similar to that of paper.

An OLED includes a first electrode as an anode connected to a thin film transistor formed in each of a plurality of sub-pixel regions of a substrate, an EML, and a second electrode as a cathode. In such OLEDs, when voltage is applied between first and second electrodes, holes and electrons are recombined in an organic EML, forming excitons, and the excitons drop to a ground state, whereby light is emitted.

However, characteristics of OLEDs are easily deteriorated due to external factors, such as external moisture, oxygen, ultraviolet light, manufacturing conditions of OLEDs, and the like. Thus, a general OLED display device includes a protective film to cover OLEDs and an encapsulation substrate that is formed on the protective film and made of glass or plastic. However, side surfaces of an OLED display device cannot be protected by an encapsulation substrate and thus moisture and oxygen permeate into the OLED display device through the side surfaces thereof.

### SUMMARY OF THE INVENTION

Accordingly, the present invention is directed to an organic light emitting diode display device and a method of manufacturing the same that substantially obviate one or more problems due to limitations and disadvantages of the related art.

An object of the present invention is to provide an organic light emitting diode display device wherein permeation of moisture and oxygen into side surfaces thereof is prevented, whereby reliability may be enhanced, and a method of manufacturing the same.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, an organic light emitting diode (OLED) display device includes a substrate, an OLED including a first electrode, an organic emission layer, and a second electrode sequentially formed on the substrate, a protective film formed on the OLED, an encapsulation substrate adhered to an entire surface of the protective film via an adhesive, and a side protective film including a silica film formed by curing a polysilazane solution so as to surround edges of elements between the substrate and the encapsulation substrate.

The polysilazane solution may include polysilazane including at least one material selected from an acryl group, an epoxy group, and a silicon group.

The side protective film may have a thickness of 50 μm to 3000 μm.

The side protective film may overlap edges of a lower surface of the encapsulation substrate by 50 μm to 500 μm.

The adhesive may be formed so as to cover edges of the protective film.

In another aspect of the present invention, a method of manufacturing an organic light emitting diode (OLED) display device includes forming an OLED including a first electrode, an organic emission layer, and a second electrode sequentially formed on a substrate, forming a protective film on the OLED, adhering an encapsulation substrate to an entire surface of the protective film via an adhesive, coating a polysilazane solution along an edge portion of the substrate, and forming a side protective film surrounding an exterior of elements between the substrate and the encapsulation substrate by curing the polysilazane solution.

The coating may be performed using a syringe or a dispenser.

The polysilazane solution may include polysilazane including at least one material selected from an acryl group, an epoxy group, and a silicon group.

The side protective film may include a silica film formed by performing photocuring or thermal curing of the polysilazane solution.

The side protective film may have a thickness of 50 μm to 3000 μm.

The side protective film may overlap edges of a lower surface of the encapsulation substrate by 50 μm to 500 μm.

The adhesive may be formed so as to cover edges of the protective film.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a sectional view of an organic light emitting diode (OLED) display device according to the present invention;

FIGS. 2A and 2B are photographs showing reliability of a general OLED display device;

FIGS. 3A and 3B are photographs showing reliability of an OLED display device according to the present invention;

FIGS. 4A through 4G are sectional views illustrating a method of manufacturing the OLED display device, according to the present invention; and

FIG. 5 illustrates that a silica film is formed by curing a polysilazane solution.

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

Hereinafter, an organic light emitting diode (OLED) display device according to the present invention will be described in detail with reference to the accompanying drawings.

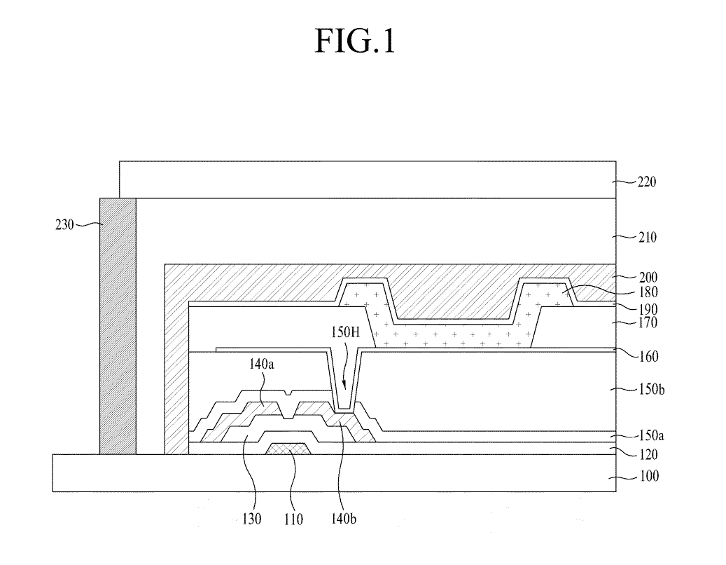

FIG. 1 is a sectional view of an OLED display device according to the present invention.

As illustrated in FIG. 1, the OLED display device according to the present invention includes a substrate 100, a thin film transistor (TFT) formed on the substrate 100, an OLED connected to the TFT, a protective film 200 formed so as to cover the OLED, an encapsulation substrate 220 adhered to the substrate 100 via an adhesive 210, and a side protective film 230 formed so as to surround the exterior of the elements between the substrate 100 and the encapsulation substrate 220.

In particular, the TFT is formed on the substrate 100. The TFT includes a gate electrode 110, a gate insulating film 120 formed so as to cover the gate electrode 110, a semiconductor layer 130 formed on the gate insulating film 120 to correspond to the gate electrode 110, and source and drain electrodes 140a and 140b formed on the semiconductor layer 130 to be spaced apart from each other.

To cover the TFT, an inorganic film 150a and an organic film 150b are sequentially formed over the entire surface of the substrate 100. The organic film 150b serves to planarize the substrate 100 with the TFT formed thereon, and the inorganic film 150a serves to enhance stability of an interface between the organic film 150b and each of the gate insulating film 120 and the source and drain electrodes 140a and 140b.

The OLED includes a first electrode 160 connected to the drain electrode 140b of the TFT, an organic emission layer (EML) 180, and a second electrode 190. The first electrode 160 is electrically connected to the drain electrode 140b of the TFT via a drain contact hole 150H formed by selectively removing the inorganic film 150a and the organic film 150b to expose the drain electrode 140b.

A bank insulating film 170 is formed on the organic film 150b so as to expose a portion of the first electrode 160, and the organic EML 180 is formed on the portion of the first electrode 160 exposed by the bank insulating film 170. In addition, the second electrode 190 is formed on the organic EML 180. In the above-described OLED, when voltage is applied between the first and second electrodes 160 and 190, holes and electrons are recombined in the organic EML 180, forming excitons, and the excitons drop to a ground state, whereby light is emitted.

In this regard, when light emitted from the organic EML 180 is emitted to the outside via the substrate 100, the first electrode 160 is formed of a transparent conductive material such as tin oxide (TO), indium tin oxide (ITO), indium zinc oxide (IZO), indium tin zinc oxide (ITZO), or the like, and the second electrode 190 is formed of an opaque conductive material such as aluminum (Al) with high reflectance, or the like.

On the other hand, when light emitted from the organic EML 180 is emitted to the outside via the encapsulation substrate 220, the first electrode 160 is formed of an opaque conductive material, and the second electrode 190 is formed of a transparent conductive material.

The protective film 200 is formed on the OLED. The protective film 200 is formed between the OLED and the adhesive 210 to prevent damage to the OLED due to moisture, oxygen, or the like or deterioration of luminescent characteristics of the OLED. In particular, the protective film 200 may surround edges of the inorganic film 150a and the organic film 150b so that the protective film 200 completely covers the OLED.

The protective film 200 may be formed as a single layer formed of an inorganic insulating material such as silicon oxide (SiO), silicon nitride (SiNₓ), or the like, or an organic insulating material such as photoacryl, or the like, or may have a multilayer structure in which a layer of the inorganic insulating material and a layer of the organic insulating material are stacked upon one another.

The encapsulation substrate 220 is adhered to the substrate 100 via the adhesive 210 that is formed on the entire surface of the encapsulation substrate 220 and is formed of a resin-based material so as to encapsulate the OLED. In this regard, the adhesive 210 may be formed only on an upper surface of the protective film 200, or, as illustrated in FIG. 1, the adhesive 210 may cover edges of the protective film 200.

The side protective film 230 is formed along the exterior of the elements between the substrate 100 and the encapsulation substrate 220. In general, side surfaces of an OLED display device are not protected by an encapsulation substrate and thus moisture and oxygen permeate into the OLED display device via an adhesive. Thus, the OLED display device according to the present invention includes the side protective film 230 and thus permeation of moisture and oxygen into side surfaces of the OLED display device may be prevented.

The side protective film 230 is formed using a polysilazane-based compound. In particular, a polysilazane solution, prepared by dissolving, in a solvent, polysilazane including at least one material selected from an acryl group, an epoxy group, and a silicon group, is coated along an edge portion of the substrate 100.

In this regard, when heat or ultraviolet light is applied thereto, the polysilazane solution is cured to form, as an inorganic film, a silica film formed of silicon oxide (Si—O) as a main component. That is, the side protective film 230 has a structure in which inorganic and organic structures are chemically combined with each other and has high moisture permeation resistance and excellent flexibility. Moreover, viscosity, thickness, or the like of the side protective film 230 is easily adjusted through changes of the organic structure.

The polysilazane solution may include polysilazane, a solvent, a photo initiator, a curing accelerator, and the like. The curing accelerator enables the polysilazane solution to be cured at low temperatures, and non-limiting examples thereof include N-heterocyclic compounds, alkanolamines, amines, acids, platinum-based catalysts, palladium-based catalysts, and rhodium-based catalysts.

As the photoinitiator, benzoin ether, diethoxyacetophenone, benzoin, xanthone, thioxanthone, isopropylthioxanthone, benzophenone, quinone, benzophenone-containing siloxane, or the like may be used. Non-limiting examples of the solvent include aromatic compounds such as benzene, toluene, xylene, ethylbenzene, diethylbenzene, trimethylbenzene, triethylbenzene, and decahydronaphthalene; saturated hydrocarbon compounds such as n-pentane, i-pentane, n-hexane, i-hexane, n-heptane, i-heptane, n-octane, i-octane, n-nonane, i-nonane, n-decane, and i-decane; saturated cyclic hydrocarbon compounds such as ethylcyclohexane, methylcyclohexane, and cyclohexane; unsaturated cyclic hydrocarbon compounds such as cyclohexene, p-methane, dipentene, and limonene; ethyls such as dipropylether, dibutylether, diethylether, methyl-t-butyl ether, and anisole; and ketones.

When the thickness of the side protective film 230 is too small, resistance to moisture and oxygen permeation is reduced. On the other hand, when the thickness of the side protective film 230 is too great, the likelihood of cracking is high. Thus, the thickness of the side protective film 230 may be between 50 and 3000 μm. In addition, the side protective film 230 may overlap edges of a lower surface of the encapsulation substrate 220 by 50 μm to 500 μm. This is because the side protective film 230 supports between the encapsulation substrate 220 and the substrate 100 so that a gap therebetween is maintained constant.

In particular, when the side protective film 230 overlaps the edges of a lower surface of the encapsulation substrate 220, the side protective film 230 completely surrounds side surfaces of the adhesive 210, whereby permeation of moisture and oxygen into the OLED display device may be efficiently prevented.

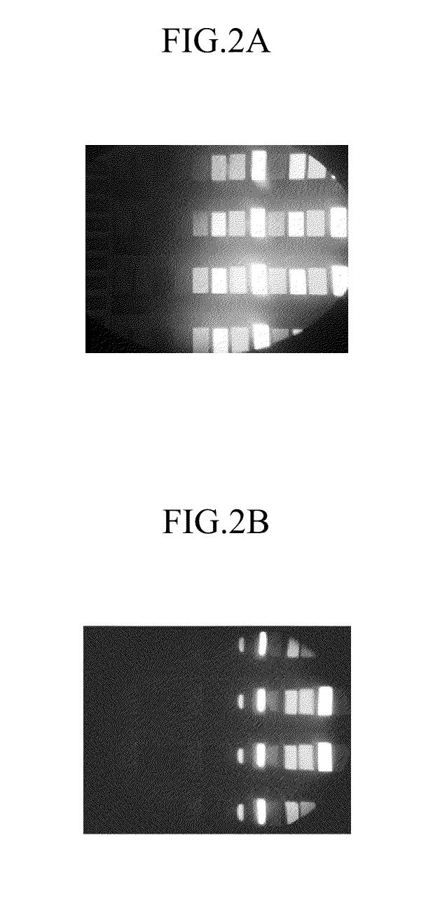

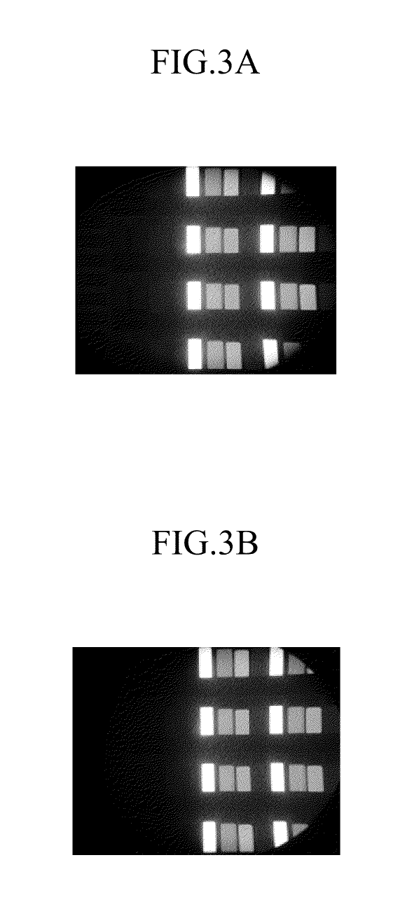

FIGS. 2A and 2B are photographs showing reliability of a general OLED display device. FIGS. 3A and 3B are photographs showing reliability of an OLED display device according to the present invention.

FIGS. 2A and 2B respectively illustrate a photograph taken before exposure and a photograph taken by exposing the general OLED display device to high temperature and high humidity conditions (85° C., 85% RH) for 800 hours. As illustrated in FIGS. 2A and 2B, moisture permeates into edges of the general OLED display device over time and thus luminescent characteristics thereof are deteriorated.

However, the OLED display device according to the present invention includes the side protective film 230, and thus, permeation of moisture and oxygen into the OLED display device through side surfaces thereof may be prevented. FIGS. 3A and 3B respectively illustrate a photograph taken before exposure and a photograph taken by exposing the OLED display device according to the present invention to high temperature and high humidity conditions (85° C., 85% RH) for 1000 hours. As illustrated in FIGS. 3A and 3B, luminescent characteristics of edges of the OLED display device according to the present invention remain the same over time.

In particular, a general OLED display device includes a thick protective film to prevent permeation of moisture and oxygen. However, the protective film is formed using vacuum deposition equipment and thus manufacturing time increases as the thickness of the protective film increases. According to the present invention, however, the side protective film 230 is formed along the exterior of the elements between the substrate 100 and the encapsulation substrate 220, and thus, permeation of moisture and oxygen into the OLED display device may be efficiently prevented even though the protective film 200 for covering the OLED is thin.

Hereinafter, a method of manufacturing the OLED display device will be described in detail with reference to the accompanying drawings.

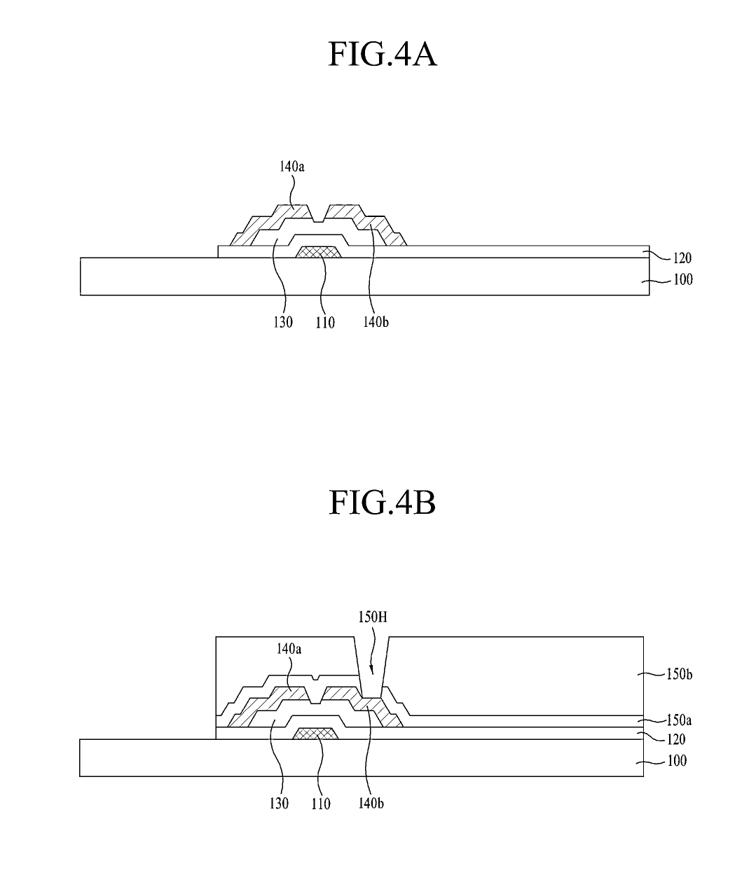

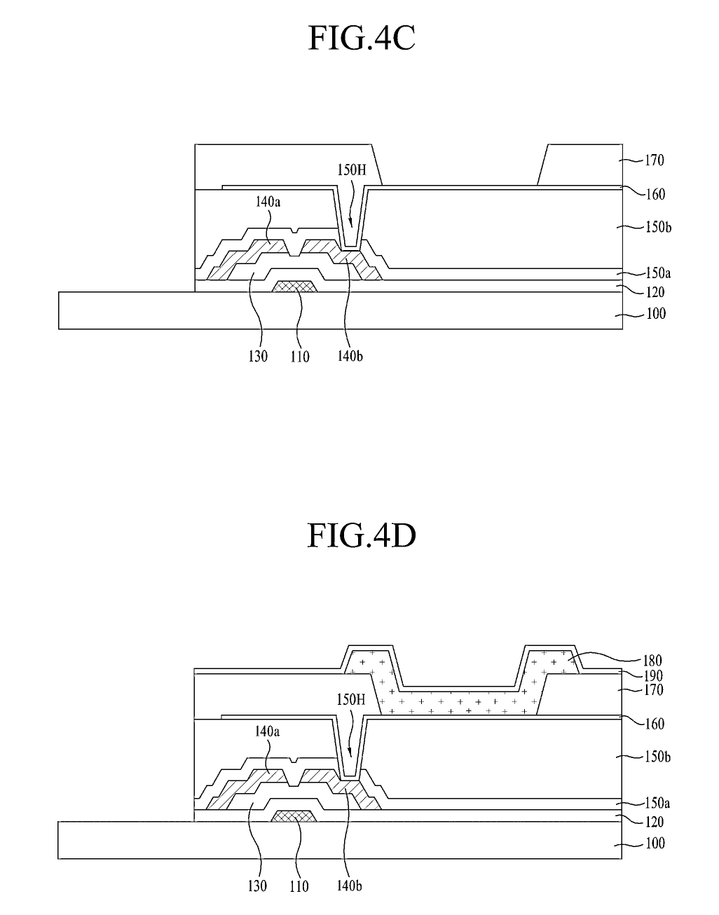

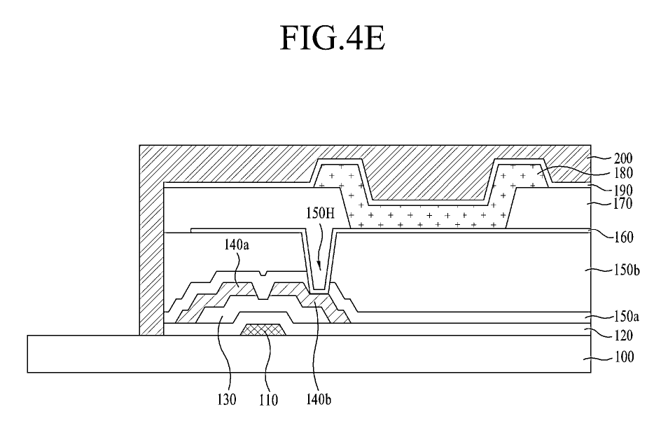

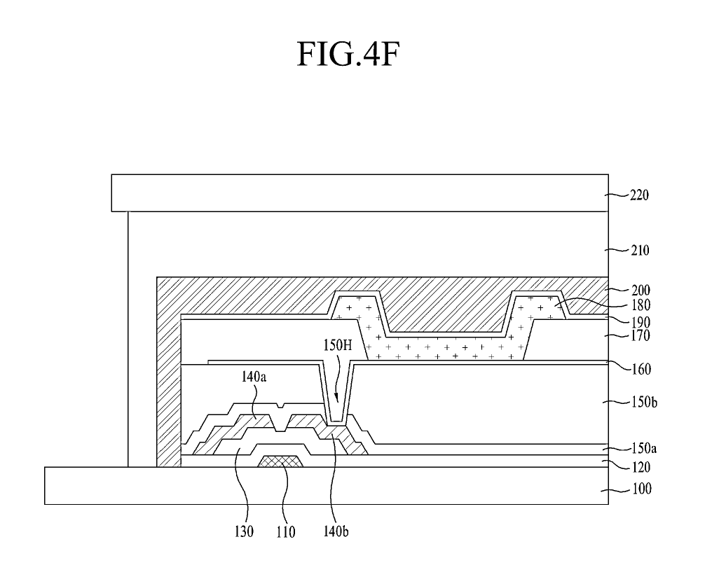

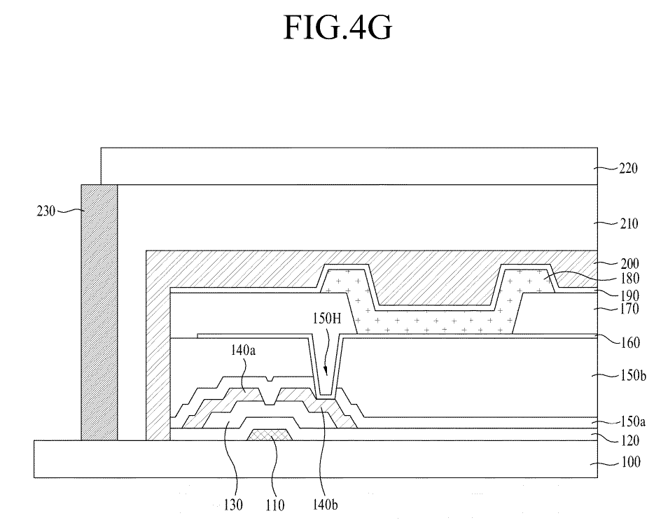

FIGS. 4A through 4G are sectional views illustrating a method of manufacturing the OLED display device, according to the present invention.

As illustrated in FIG. 4A, a TFT including the gate electrode 110, the gate insulating film 120, the semiconductor layer 130, the source electrode 140a, and the drain electrode 140b is formed on the substrate 100.

In particular, a gate metal layer is formed on the substrate 100 through deposition such as sputtering or the like. The gate metal layer is formed of a metal such as an aluminum (Al)-based metal (e.g., Al or AlNd), copper (Cu), titanium (Ti), molybdenum (Mo), tungsten (W), or the like and is patterned by photolithography and etching to form the gate electrode 110.

Subsequently, the gate insulating film 120 is formed on the substrate 100 using an inorganic insulating material such as silicon oxide (SiOₓ), silicon nitride (SiNₓ), or the like so as to cover the gate electrode 110. The semiconductor layer 130 is formed on the gate insulating film 120 to correspond to the gate electrode 110, and a data metal layer is formed on the substrate 100 with the semiconductor layer 130 formed thereon through deposition such as sputtering or the like.

The data metal layer is formed of Ti, W, an Al-based metal, Mo, Cu, or the like. The data metal layer is patterned by photolithography and etching to form the source electrode 140a and the drain electrode 140b spaced apart from each other so as to expose an upper surface of the semiconductor layer 130.

Subsequently, as illustrated in FIG. 4B, the inorganic film 150a is formed on the substrate 100 with the source and drain electrodes 140a and 140b formed thereon, using silicon oxide (SiOₓ), silicon nitride (SiNₓ), or the like. Thereafter, the organic film 150b is formed on the inorganic film 150a using an acryl-based resin, or the like. Then, the inorganic film 150a and the organic film 150b are selectively removed by photolithography and etching to form the drain contact hole 150H for exposing the drain electrode 140b.

As illustrated in FIG. 4C, the first electrode 160 is formed on the organic film 150b through deposition such as sputtering or the like. The first electrode 160 is connected to the drain electrode 140b via the drain contact hole 150H. Thereafter, the bank insulating film 170 is formed so as to expose a portion of the first electrode 160. The bank insulating film 170 defines a light-emitting region of the OLED and prevents light leakage from a non-light-emitting region.

As illustrated in FIG. 4D, the organic EML 180 is formed on the portion of the first electrode 160 exposed by the bank insulating film 170, and the second electrode 190 is formed on the organic EML 180. Next, as illustrated in FIG. 4E, the protective film 200 is formed on the substrate 100 with the second electrode 190 formed thereon.

The protective film 200 may be formed as a single layer formed of an inorganic insulating material such as aluminum oxide (AlOₓ), silicon oxynitride (SiON), silicon nitride (SiNₓ), silicon oxide (SiOₓ), or the like, or an organic insulating material such as benzocyclobutene, photoacryl, or the like, or may have a multilayer structure in which a layer of the inorganic insulating material and a layer of the organic insulating material are stacked one upon another. In particular, the protective film 200 may be formed so as to cover edges of the inorganic film 150a and the organic film 150b so that the protective film 200 completely covers the OLED.

Next, as illustrated in FIG. 4F, the substrate 100 with the protective film 200 formed thereon is adhered to the encapsulation substrate 220 via the adhesive 210. In particular, the adhesive 210 is formed over the entire surface of the encapsulation substrate 220, and the substrate 100 and the encapsulation substrate 220 are adhered to each other via the adhesive 210 after arrangement such that the encapsulation substrate 220 and the substrate 100 with the protective film 200 formed thereon face each other.

In this regard, the encapsulation substrate 220 corresponds to an upper surface of the protective film 200 and thus, as illustrated in FIG. 4G, the side protective film 230 is formed along the exterior of the elements between the substrate 100 and the encapsulation substrate 220 so as to surround side surfaces of the adhesive 210. In this regard, the side protective film 230 is formed by coating a polysilazane solution along an edge portion of the substrate 100 using a syringe or a dispenser and performing photocuring or thermal curing thereof.

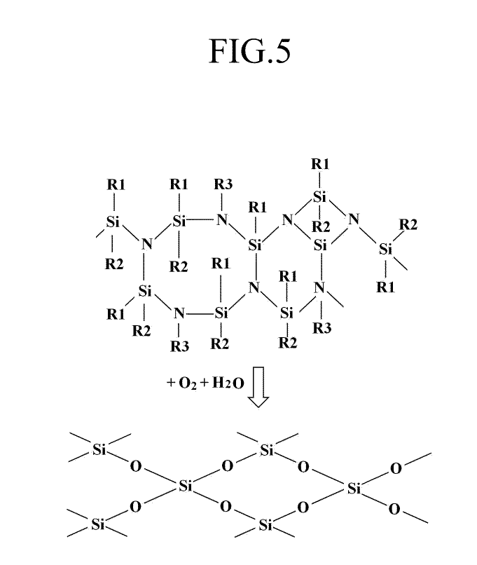

FIG. 5 illustrates that a silica film is formed by curing the polysilazane solution.

In particular, the polysilazane solution, prepared by dissolving, in a solvent, polysilazane including at least one material selected from an acryl group, an epoxy group, and a silicon group, is coated along the edge portion of the substrate 100. Thereafter, the coated polysilazane solution is thermally cured or photocured by heating at a temperature of 100° C. to 110° C. or through ultraviolet (UV) exposure under a single atmosphere of oxygen, water, or hydrogen peroxide or under a mixed atmosphere and, as a result, a silica film formed of silicon oxide (Si—O) as a main component, which is an inorganic film, is formed such that Si—N bonds of polysilazane are combined with oxygen and nitrogen (N) atoms are dissociated therefrom.

The silica film has a structure in which inorganic and organic structures are chemically combined with each other and has high moisture permeation resistance and excellent flexibility. Moreover, viscosity, thickness, or the like of the silica film is easily adjusted through changes in the organic structure.

The side protective film 230 may have a thickness between 50 and 3000 μm. When the thickness of the side protective film 230 is too small, resistance to moisture and oxygen permeation is reduced. On the other hand, when the thickness of the side protective film 230 is too great, the likelihood of cracking is high.

In addition, the side protective film 230 may overlap edges of a lower surface of the encapsulation substrate 220 by 50 μm to 500 μm. In this case, the side protective film 230 supports between the encapsulation substrate 220 and the substrate 100 so that a gap therebetween is maintained constant.

In the above-described method of manufacturing the OLED display device according to the present invention, the side protective film 230 is formed along the exterior of the elements between the encapsulation substrate 220 and the substrate 100, whereby permeation of moisture and oxygen into the OLED display device through side surfaces thereof may be prevented. In particular, a general OLED display device includes a thick protective film to prevent permeation of moisture and oxygen. However, the protective film is formed using vacuum deposition equipment and thus manufacturing time increases as the thickness of the protective film increases.

According to the present invention, however, the side protective film 230 may be formed using simplified manufacturing processes such that the polysilazane solution is coated on an edge region of the substrate 100 so as to surround edges of the elements between the substrate 100 and the encapsulation substrate 220 and then is cured by heat or light. Thus, in the OLED display device according to the present invention, permeation of moisture and oxygen into the OLED display device may be efficiently prevented by the side protective film 230 even through the protective film 200 is thin.

As is apparent from the foregoing description, a side protective film is formed along the exterior of elements between an encapsulation substrate and a substrate and thus permeation of moisture and oxygen into an OLED display device through side surfaces thereof may be prevented. In particular, a silica film may be formed as the side protective film along the exterior of the elements between the substrate and the encapsulation substrate by coating a polysilazane solution along an edge portion of the substrate and curing the polysilazane solution using light or heat, whereby reliability of the OLED display device may be enhanced using simplified manufacturing processes.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. An organic light emitting diode (OLED) display device comprising:
a substrate;
an OLED comprising a first electrode, an organic emission layer, and a second electrode sequentially formed on the substrate;
a protective film formed on the OLED;
an encapsulation substrate adhered to an entire surface of the protective film via an adhesive; and
a side protective film comprising a silica film formed by curing a polysilazane solution so as to surround edges of elements between the substrate and the encapsulation substrate.

2. The OLED display device according to claim 1, wherein the polysilazane solution comprises polysilazane comprising at least one material selected from an acryl group, an epoxy group, and a silicon group.

3. The OLED display device according to claim 1, wherein the side protective film has a thickness of 50 μm to 3000 μm.

4. The OLED display device according to claim 1, wherein the side protective film overlaps edges of a lower surface of the encapsulation substrate by 50 μm to 500 μm.

5. The OLED display device according to claim 1, wherein the adhesive is formed so as to cover edges of the protective film.

6. A method of manufacturing an organic light emitting diode (OLED) display device, the method comprising:
forming an OLED comprising a first electrode, an organic emission layer, and a second electrode sequentially formed on a substrate;
forming a protective film on the OLED;
adhering an encapsulation substrate to an entire surface of the protective film via an adhesive;
coating a polysilazane solution along an edge portion of the substrate; and
forming a side protective film surrounding an exterior of elements between the substrate and the encapsulation substrate by curing the polysilazane solution.

7. The method according to claim 6, wherein the coating is performed using a syringe or a dispenser.

8. The method according to claim 6, wherein the polysilazane solution comprises polysilazane comprising at least one material selected from an acryl group, an epoxy group, and a silicon group.

9. The method according to claim 6, wherein the side protective film comprises a silica film formed by performing photocuring or thermal curing of the polysilazane solution.

10. The method according to claim 6, wherein the side protective film has a thickness of 50 μm to 3000 μm.

11. The method according to claim 6, wherein the side protective film overlaps edges of a lower surface of the encapsulation substrate by 50 μm to 500 μm.

12. The method according to claim 6, wherein the adhesive is formed so as to cover edges of the protective film.
